(19) United States
(12) Patent Application Publication
(10) Pub. No.: US 2026/0015769 A1
(43) Pub. Date: Jan. 15, 2026

(54) METHODS TO ENHANCE AND CHARACTERIZE OXYGEN PRECIPITATION INDUCED DEFECTS DURING A WAFER POLISHING SEQUENCE

(71) Applicant: GlobalWafers Co., Ltd., Hsinchu (TW)

(72) Inventors: Zheng Lu, O'Fallon, MO (US); Shan-Hui Lin, Hsinchu City (TW)

(21) Appl. No.: 19/260,878

(22) Filed: Jul. 7, 2025

Related U.S. Application Data
(60) Provisional application No. 63/669,659, filed on Jul. 10, 2024.

(51) Int. Cl. C30B 33/02; C30B 15/20; C30B 29/06

(52) U.S. Cl. CPC C30B 33/02; C30B 15/20; C30B 29/06

(57) ABSTRACT

Methods for detecting oxygen precipitation induced defects during a polishing sequence. The methods are suited for detecting oxygen precipitates in heavily doped boron single crystal silicon wafers or in lightly doped wafers that are COP-free. The methods may involve inspecting a silicon wafer for LLS defects after a thermal anneal followed by a polishing sequence.

### CROSS-REFERENCE TO RELATED APPLICATIONS

This application claims the benefit of U.S. Provisional Patent Application No. 63/669,659, filed Jul. 10, 2024, which is incorporated herein by reference in its entirety.

### FIELD OF THE DISCLOSURE

The field of the disclosure relates to methods for detecting oxygen precipitation induced defects during polishing sequences and, in particular, for detecting oxygen precipitates in heavily doped boron single crystal silicon wafers.

### BACKGROUND

During Czochralski silicon crystal growth, besides the usual agglomerated interstitial and vacancy defects, there are many oxygen precipitates which have a wide size distribution. Many of the defects are extremely small (e.g., nanometers) and are difficult to detect. It is common that such oxygen precipitates in the bulk of as-grown crystal substrates interact with the wafering process and appear on the polished wafer surface. These defects are often mischaracterized as wafering induced defects or a different type of crystal defects due to the lack of capability to characterize and differentiate these different species of defects. Mischaracterizing the oxygen precipitates as crystal voids or wafering induced surface defects often leads to a wrong solution being pursued to eliminate the defects. Such mischaracterization occurs with increasing frequency with the implementation of the new generation of surface defect detection tools capable of detecting small size defects.

A need exists for methods for detecting and characterizing oxygen precipitation induced defects during polishing sequences.

### SUMMARY

One aspect of the present disclosure is directed to a method for detecting oxygen precipitates in silicon wafers during a polishing sequence. A silicon wafer is annealed to at least 1000° C. for at least 0.5 hours to increase the size of oxygen precipitates present in the silicon wafer. The silicon wafer is boron doped and has a resistivity of less than 20 mohm-cm. The silicon wafer is polished in a first polishing step after annealing the silicon wafer. The first polishing step is a double-side polish. The silicon wafer is polished in a second polishing step after the first polishing step. The second polishing step is a finish polish. The silicon wafer is inspected for defects in an inspection step. The inspection step is after the second polishing step. The inspection step includes directing light to a front surface of the silicon wafer and detecting scattered reflected light. Light scattering events on the front surface of the silicon wafer are identified based on the reflected light.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section of an ingot puller apparatus before silicon ingot growth.

FIG. 2 is a cross-section of the ingot puller apparatus of FIG. 1 during silicon ingot growth.

FIG. 3 is a cross-section view of a semiconductor wafer.

FIG. 4 is an embodiment of a method for detecting oxygen precipitates in silicon wafers during a polishing sequence.

FIG. 5 is another embodiment of a method of the present disclosure for detecting oxygen precipitates in silicon wafers during a polishing sequence.

FIG. 6 shows LLS particle maps after a standard double-side polish and finish polish sequence (left) and after a standard double-side polish and finish polish sequence plus repolishing (right).

FIG. 7 shows LLS particle maps taken from the seed end (left panel), mid-portion (center panel) and opposite end (right panel) after the polishing sequence of FIG. 5 with the anneal omitted.

FIG. 8 shows LLS particle maps taken from the seed end (left panel), mid-portion (center panel) and opposite end (right panel) after a polishing sequence with thermal treatment.

### DETAILED DESCRIPTION

Provisions of the present disclosure relate to methods for detecting oxygen precipitates in silicon wafers during a polishing sequence and to methods for preparing single crystal silicon ingots. Silicon wafers may be analyzed to determine the as-grown oxygen precipitates during a polishing sequence of the semiconductor wafers.

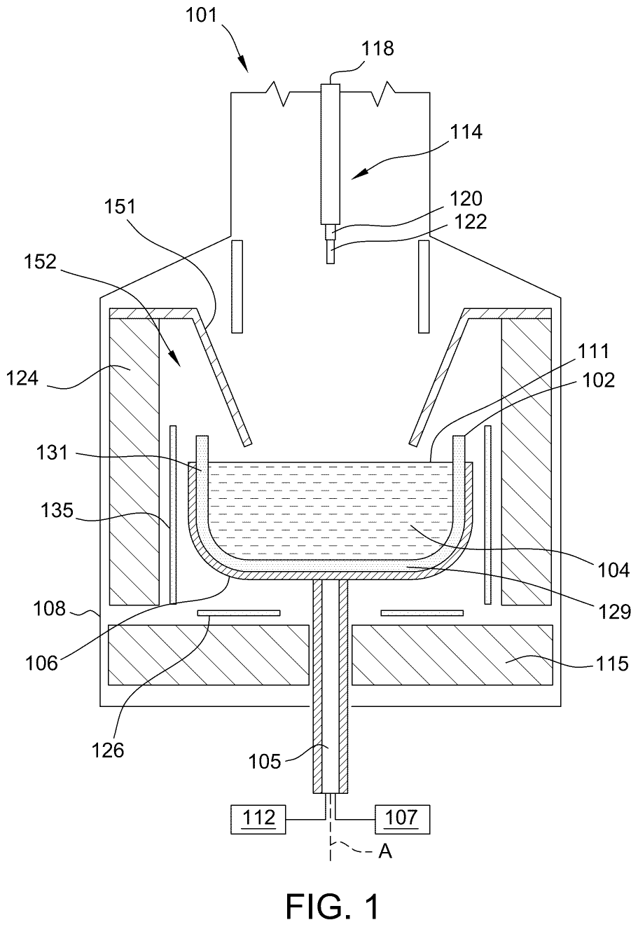

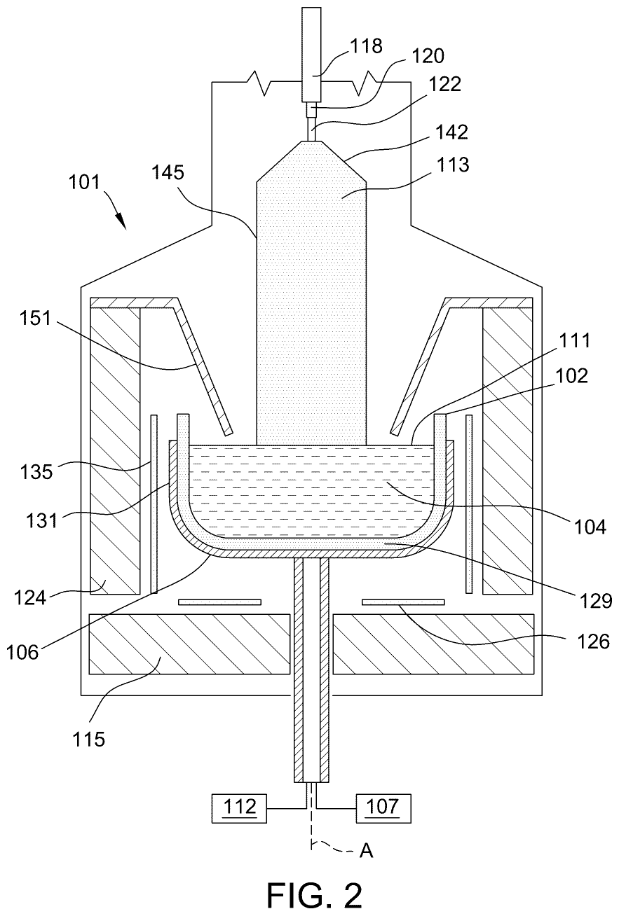

The methods of the present disclosure may generally be carried out in any ingot puller apparatus that is configured to pull a single crystal silicon ingot. An example ingot puller apparatus (or more simply “ingot puller”) is indicated generally at “101” in FIG. 1. The ingot puller apparatus 101 includes a crucible 102 for holding a melt 104 of semiconductor or solar-grade material, such as silicon, supported by a susceptor 106. The ingot puller apparatus 101 includes a crystal puller housing 108 that defines a growth chamber 152 for pulling a silicon ingot 113 (FIG. 2) from the melt 104 along a pull axis A.

The crucible 102 includes a floor 129 and a sidewall 131 that extends upward from the floor 129. Within the crucible 102 is a silicon melt 104 having a melt surface 111 (i.e., melt-ingot interface).

In some embodiments, the crucible 102 is layered. For example, the crucible 102 may be made of a quartz base layer and a synthetic quartz liner disposed on the quartz base layer.

The susceptor 106 is supported by a shaft 105. The susceptor 106, crucible 102, shaft 105 and ingot 113 (FIG. 2) have a common longitudinal axis A or “pull axis” A.

A pulling mechanism 114 is provided within the ingot puller apparatus 101 for growing and pulling an ingot 113 from the melt 104. Pulling mechanism 114 includes a pulling cable 118, a seed holder or chuck 120 coupled to one end of the pulling cable 118, and a silicon seed crystal 122 coupled to the seed holder or chuck 120 for initiating crystal growth. One end of the pulling cable 118 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to cause the seed crystal 122 to rise. This causes a single crystal ingot 113 (FIG. 2) to be withdrawn from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. For example, the crucible 102 may be at a lowest position (near the bottom heater 126) in which an initial charge of solid-phase polycrystalline silicon previously added to the crucible 102 is melted. Crystal growth commences by contacting the melt 104 with the seed crystal 122 and lifting the seed crystal 122 by the pulling mechanism 114. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 101 (FIG. 2).

A crystal drive unit (not shown) may also rotate the pulling cable 118 and ingot 113 (FIG. 2) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 101 may include an inert gas system to introduce and withdraw an inert gas such as argon from the growth chamber 152. The ingot puller apparatus 101 may also include a dopant feed system (not shown) for introducing dopant into the melt 104.

According to the Czochralski single crystal growth process, a quantity of polycrystalline silicon, or polysilicon, is charged to the crucible 102. The initial semiconductor or solar-grade material that is introduced into the crucible is melted by heat provided from one or more heating elements to form a silicon melt in the crucible. The ingot puller apparatus 101 includes bottom insulation 115 and side insulation 124 to retain heat in the ingot puller apparatus. In the illustrated embodiment, the ingot puller apparatus 101 includes a bottom heater 126 disposed below the crucible floor 129. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to pull the seed crystal 122 from the melt 104. Referring now to FIG. 2, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The ingot puller apparatus 101 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 101 may include a heat shield 151. The heat shield 151 may shroud the ingot 113 during crystal growth (FIG. 2).

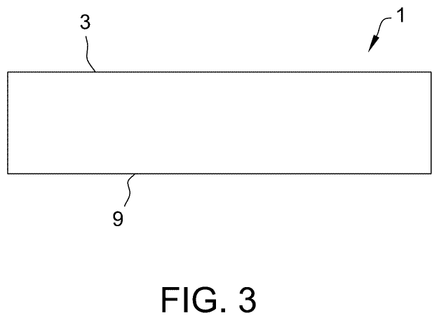

Once the ingot 113 has been grown, the ingot 113 is sliced into a plurality of silicon substrates (i.e., wafers). The substrate is a single crystal silicon wafer. Referring now to FIG. 3, each wafer 1 has a front surface 3 and a back surface 9.

In accordance with embodiments of the present disclosure, a silicon wafer may be analyzed to determine the as-grown oxygen precipitates during a polishing sequence of the semiconductor wafer. While the methods of the present disclosure may be described herein with respect to a process for growing a single crystal silicon ingot, the one or more methods may be a standalone method for detecting oxygen precipitates in silicon wafers during a polishing sequence (e.g., from wafers obtained commercially from a third party or the like). Further, the silicon wafers that are analyzed according to the methods described herein may be sliced from the same single crystal silicon ingot or from different single crystal silicon ingots.

In some embodiments, the semiconductor silicon wafers that are analyzed are heavily boron doped such as doping to P+(e.g., 10 mohm-cm to 20 mohm-cm) or P++(e.g., 5 mohm-cm to 10 mohm-cm) concentrations. The resistivity of the semiconductor silicon wafers may be less than 20 mohm-cm or less than 15 m-ohm-cm (e.g., from 5 mohm-cm to 20 mohm-cm). In some embodiments, the silicon wafers are lightly doped but are COP-free (i.e., free of Crystal Originated Particles which are agglomerated vacancy defects).

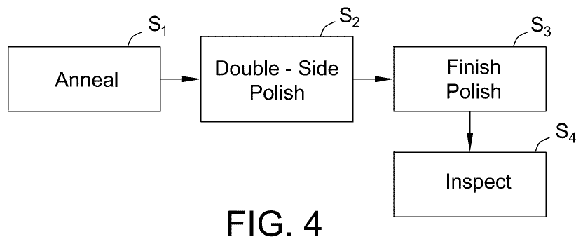

In accordance with methods of the present disclosure and with reference to FIG. 4, in a first step S₁ of embodiments of the present disclosure, a first semiconductor silicon wafer is annealed to a temperature of at least 1000° C. for at least 0.5 hours (such as 0.5 hours to 20 hours). The anneal from 0.5 hours to 20 hours) allows small oxygen precipitates present in the semiconductor silicon wafer to grow and be subsequently detected.

In some embodiments, the first semiconductor wafer is annealed to at least 1000° C. for at least 1 hour, at least 2 hours, or at least 4 hours (e.g., 0.5 hours to 20 hours, 2 hours to 20 hours or 4 hours to 20 hours) with a slow 700° C. to 1000° C. ramp such as 3-4 hours.

In some embodiments, instead of a growth anneal, it is desirable to dissolve oxygen precipitates. Oxygen precipitates may be dissolved in an anneal that includes a rapid thermal ramp from room temperature (e.g., 25° C.) to 900° C., or even to 1000° C., 1100° C., 1200° C., or 1300° C., in less than 5 minutes, or even less than 1 minute, less than 30 seconds, less than 20 seconds, less than 10 seconds, or less than 5 seconds.

After annealing, in a second step S₂, the silicon wafer is polished in a first polishing step. The first polishing step S₂ may be a double-side polish in which the front surface 3 (FIG. 3) and the back surface 9 of the wafer 1 are polished (i.e., a double-side polish is performed). Generally, the polish S₂ is a “rough” polish that reduces the surface roughness of the wafer to less than about 3.5 Å to even as low as about 2.5 Å or even about 2 Å as measured with an atomic force microscope (AFM) at scan sizes of about 1 μm× about 1 μm to about 100 μm× about 100 μm. The polishing step S₂ typically results in removal of about 1 μm to about 20 μm and, more typically, from about 5 μm to about 20 μm of material from each surface 3, 9 of the wafer 1.

The first polishing step S₂ (and the second step S₃ described below) may be achieved by, for example, chemical-mechanical planarization (CMP). CMP typically involves the immersion of the wafer in an abrasive slurry and polishing of the wafer by a polymeric pad. Through a combination of chemical and mechanical action the surface of the wafer is smoothed. Typically the polish is performed until a chemical and thermal steady state is achieved and until the wafers have achieved their targeted shape and flatness. The first polishing step S₂ may be performed on a double-side polisher commercially available from Peter Wolters (e.g., AC2000 polisher; Rendsburg, Germany) or Fujikoshi (Tokyo, Japan), Speedfam (Kanagawa, Japan). Stock removal pads for silicon polishing are available from Psiloquest (Orlando, Florida) and Dow Chemical Company (Midland, Michigan) and silica based slurries may be purchased from Dow Chemical Company, Cabot (Boston, Massachusetts), Nalco (Naperville, Illinois), Bayer MaterialScience (Leverkusen, Germany), DA NanoMaterials (Tempe, Arizona) and Fujimi (Kiyoso, Japan).

The polishing step S₂ may occur for about 5 minutes to about 60 minutes and at a pad pressure of from about 150 g/cm² to about 700 g/cm² with a slurry flow rate of about 50 ml/min to about 300 ml (or from about 75 ml/min to about 125 ml/min). However, it should be understood that other polish times, pad pressures and slurry flow rates may be used without departing from the scope of the present disclosure.

After the second polishing step S₂, the wafers may be rinsed and dried. In addition, the wafers may be subjected to a wet bench or spin cleaning. Wet bench cleaning may include contacting the wafers with SC-1 cleaning solution (i.e., ammonium hydroxide and hydrogen peroxide), optionally, at elevated temperatures (e.g., about 50° C. to about 80° C.). Spin cleaning includes contact with a HF solution and ozonated water and may be performed at room temperature.

After the first polishing step, the silicon wafer is polished in a second polishing step S₃. The second polishing step S₃ may be a “finish” or “mirror” polish in which the front surface 3 (and typically not the back surface 9) of the wafer 1 is contacted with a polishing pad attached to a turntable or platen.

The finish polish S₃ reduces the surface roughness of the wafer to less than about 2.0 Å as measured by an AFM at scan sizes of about 10 μm× about 10 μm to about 100 μm× about 100 μm. The finish polish may even reduce the surface roughness to less than about 1.5 Å or less than about 1.2 Å at scan sizes of about 10 μm× about 10 μm to about 100 μm× about 100 μm. Finish polishes typically remove only about 1.5 μm or less of material from the surface (e.g., 0.1 μm to 2.5 μm).

Suitable finish polishing apparatus may include a polishing pad that is mounted to a polishing table. Polishing heads hold substrates by use of retainers such that the front surfaces of the substrates contact the pad. Polishing slurry is supplied to the polishing pad while the polishing head oscillates at high speed to move the wafers relative to the pad to polish the front surfaces of the wafers.

Suitable polishers for finish polishing may be obtained from Lapmaster SFT (e.g., LGP-708, Chiyoda-Ku, Japan). Suitable pads include polyurethane impregnated polyethylene pads such as SUBA pads available from Dow Chemical Company, suede-type pads (also referred to as a polyurethane foam pad) such as a SURFIN pad from Fujimi, a CIEGAL pad from Chiyoda KK (Osaka, Japan) and a SPM pad from Dow Chemical Company.

The finish polish step S₃ (i.e., first table of the finish polish) may occur for at least about 60 seconds or even about 90, 120 or 180 seconds. The total slurry flow rate may range from about 500 ml/min to about 1000 ml/min (total as mixed) and the pad pressure may range from about 60 g/cm² to about 200 g/cm²; however, it should be understood that other polish times, pad pressures and slurry flow rates may be used without departing from the scope of the present disclosure. One or more polishing slurries may be supplied to the polishing pad at various sequences of the finish polish.

Once the second polishing step S₃ is complete, the silicon wafer is inspected in step S₄. The inspection step S₄ may be an inspection step in which the wafer is placed in an inspection tool in which the inspection tool directs light to the front surface 3 of the semiconductor wafer 1 with the tool detecting scattered reflected light. The light scattering events (i.e., Laser Light Scattering or “LLS”) on the front surface of the semiconductor silicon wafer are identified based on the reflected light. For example, the inspection tool may output defects and/or defect counts (e.g., light point defects and non-cleanable light point defect (“LPD+LPDN”)) as LLS.

The inspection tool may be any suitable inspection tool that determines LLS on a surface of a wafer. Commercially available tools include the SURFSCAN SP7XP available from KLA-Tencor (Milpitas, California). The SP7XP tool involves advanced surface defect detection with small size defect detection capability. The SP7XP tool may classify LPD+LPDN with a relatively high narrow channel to wide channel ratio. The SP7XP tool may be operated in a high-sensitivity mode to detect defects.

In some embodiments, the inspected silicon wafer is compared to a second silicon wafer which was processed as in FIG. 4 with the anneal omitted to determine the extent at which LLS are attributable to oxygen precipitates. Polishing steps S₂ and S₃ may generally be performed under the same conditions (e.g., polishing pads, chemistry, length, etc.). After the first and second polishing steps S₂, S₃, the second silicon wafer is also inspected for defects in inspection step S₄ (i.e., without the second silicon wafer being annealed before inspection step S₄).

Once both wafers are inspected, a density of light scattering events on the front surface of the first silicon wafer may be compared to a density of light scattering events on the front surface of the second silicon wafer (e.g., by a user). The density could be the total defect count on the wafer surface or the number of defects in a particular surface area of the wafer. In some embodiments, the wafer inspection tool outputs a particle map of the first silicon wafer and a particle map of the second silicon wafer. The particle maps may be compared digitally (e.g., by the tool) to compare the density of the defects or may be compared by a user.

The characterization and detection methods described herein may be used to form a single crystal silicon ingot. For example, after the characterization and detection method described herein, an ingot is grown (as described above relating to FIGS. 1-2), and one or more growth conditions of the single crystal silicon ingot are selected based on, at least in part, the comparison of the density of light scattering events with and without the anneal. For example, a value of the one or more growth condition may be changed from the value used when an ingot from which the first and/or second silicon wafers was sliced. The growth condition may be selected from boron concentration, ingot pull rate, axial temperature gradient, reflector height.

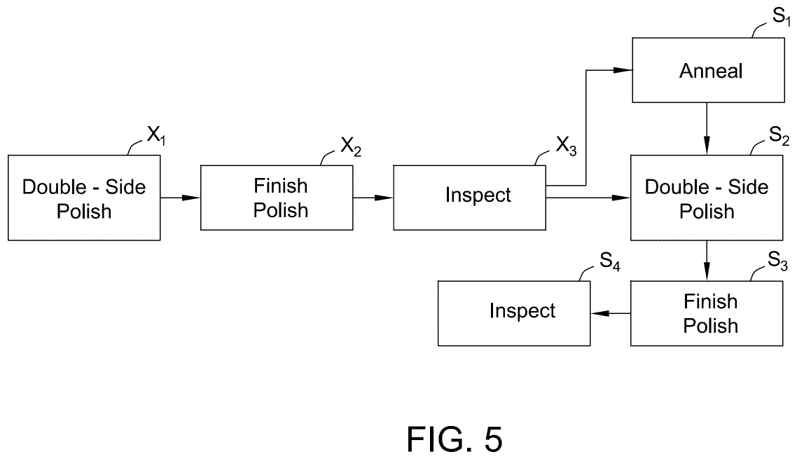

Another example method of the present disclosure is shown in FIG. 5 of the application. In FIG. 5, polishing steps S₂ and S₃ are repolishing steps and are preceded by an initial double-side polish X₁, finish polish X₂, and inspection step X₃. The particle maps from the two inspection steps X₃ and S₄ may be used to verify that the polishing sequence did not result in formation of further defects.

Compared to conventional characterization methods, the methods of the present disclosure have several advantages. The methods may involve use of advanced surface defect detection tools with small size defect detection capability to determine and characterize defects in polished silicon wafers, such as heavy boron doped wafers. The process enables characterization of small crystal bulk defects that appear on the polished wafer surface and confirms the true nature and origin of the defects.

Embodiments of the disclosed method enhance growth of oxygen precipitates and dissolve the oxygen precipitates so that detection with and without the thermal treatment allows for differentiation of the oxygen precipitates which respond to the thermal treatment from the polishing induced defects or other crystal defects that do not respond to the thermal treatment. Such characterization reduces or eliminates the wrongful determination of oxygen precipitates on the polished wafer surface of heavily boron doped crystals including both P++ and P+ as other species of defects such as wafering induced defects or crystal voids.

While heavily doped boron P++ wafers do not have crystal voids in as grow crystals, some P+wafers do due to lower boron concentration than P++. The process of the present disclosure may reduce and eliminate mischaracterization of oxygen precipitates that appear on the polished wafer surface of heavily doped boron crystals including both P++ and P+ as other species of defects such as wafering induced defects or crystal voids which occur with increasing frequency with the implementation of surface defect detection tools capable of detecting defects with small sizes.

The methods of the present disclosure may use advanced surface defect detection tools with small size defect detection capability to measure polished silicon wafers with heavy boron doping repeatedly before and after multiple specifically designed thermal treatments.

### EXAMPLES

The processes of the present disclosure are further illustrated by the following Examples. These Examples should not be viewed in a limiting sense.

### Example 1: LLS Maps After Completion of the Wafer Polishing Sequence

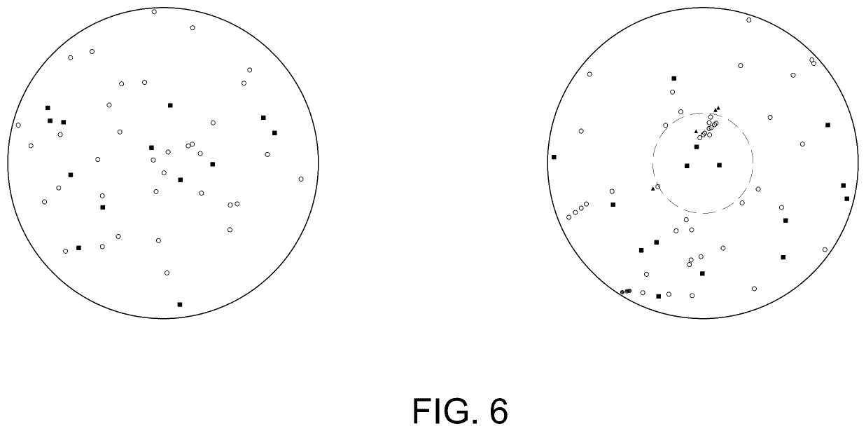

FIG. 6 shows the local light scatters (LLS) particle map of a polished P++ wafer measured by SP7 tool before and after a polishing sequence with the thermal anneal being omitted. The measurement map in the left panel is taken after the regular double-side polishing, final polishing, and JITC cleaning in standard process flow. The measurement map in the right panel was taken on the exact same wafer but after additional sequence of the same double-side polishing, final polishing and JITC cleaning (i.e., re-polish).

As shown in FIG. 6, while defects detected are at different locations after the additional polishing and cleaning sequence, the overall density and defect patterns (in this case the lack of them) are similar. FIG. 6 demonstrates that if there is no crystal induced defect, an additional sequence of the same standard double-side polishing, final polishing, and clean does not result in different LLS performance.

### Example 2: LLS Maps After Completion of an Additional Wafer Polishing Sequence with Anneal

As demonstrated in Example 1 (FIG. 6) if there are no crystal induced defects, additional sequence of the same standard double-side polishing, final polishing, and JITC cleaning will not produce different LLS performance. Therefore, if the measurement after thermal treatment designed for oxygen precipitation growth shows significantly pattern and/or with higher LPD+LPDN counts than that of the same wafer measured without thermal treatment, the contributing root cause for the defect pattern or higher defect counts is oxygen precipitation.

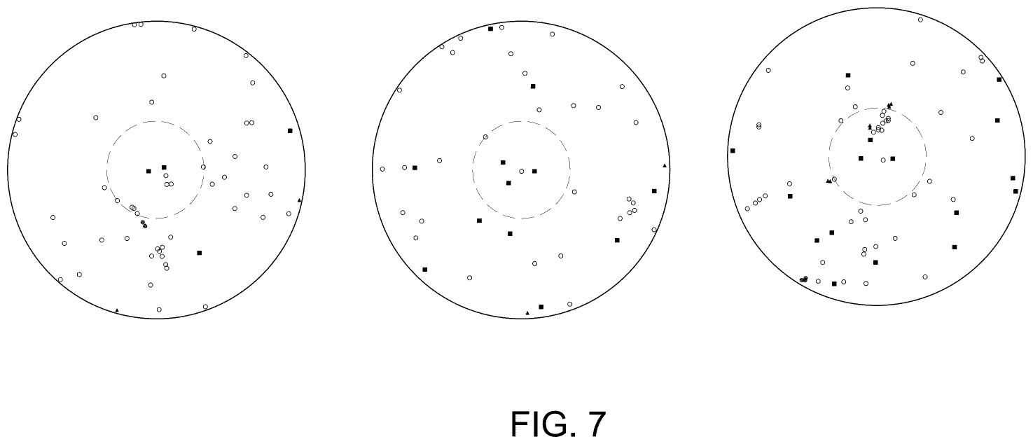

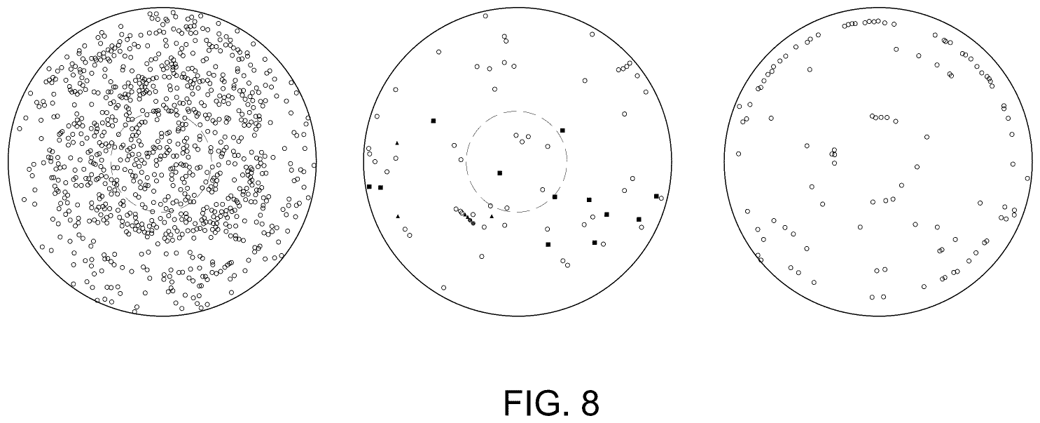

FIG. 7 shows LLS maps of the P++ substrates taken from seed end (left panel) of an ingot, from the mid-portion of an ingot (center panel) and opposite end (right panel) measured by SP7 with high sensitivity mode after standard double-side polish, finish polish and clean without any thermal treatment. FIG. 8 shows LLS maps of the same or immediate sister P++wafers measured by SP7 with the same high sensitivity mode after thermal treatment of 4 hours at 1000° C. plus additional sequence of the same polishing and cleaning.

The defect core and ring in the right panel of FIG. 8 has such a high density that the maps are saturated. A specially modified recipe has to be used only for this wafer to reduce the saturation in order to allow some part of the pattern to be shown.

As demonstrated in FIGS. 7-8, the thermal treatment designed for oxygen precipitation growth enhanced oxygen precipitation induced defects on wafers from the seed-end and opposite end which showed radially distributed defect patterns in higher density cores and rings after polishing and cleaning. Wafer from the mid-body had less of such defects or the defects have not reached the detection limit of the tool used after the 4-hour thermal treatments and additional sequence of polishing and cleaning.

The process of embodiments of the present disclosure can differentiate oxygen precipitates which responds to those thermal treatments from the polishing induced defects or other crystal defects that do not respond to those thermal treatments. The methods are well suited for heavily doped boron substrates which are COP-free or nearly COP-free wafers (i.e., for substrates without a high LLS count). The analysis methods are also suitable perfect silicon wafers.

The thermal treatments can be designed to grow the oxygen precipitates and hence the precipitation induced defect on the wafer surface after polishing and cleaning processes to be of a sufficient size to be detected by the inspection tool (e.g., in high sensitivity mode). Similarly, the thermal treatments can also be designed to dissolve oxygen precipitates and hence the precipitation induced defect on the wafer surface after polishing and cleaning processes. The high sensitivity mode in SP7 measurements may be adjusted such that it is sensitive enough to detect such precipitation induced defects and yet not to be too sensitive to cause saturation in measurements.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for detecting oxygen precipitates in silicon wafers during a polishing sequence, the method comprising:
annealing a silicon wafer to at least 1000° C. for at least 0.5 hours to increase the size of oxygen precipitates present in the silicon wafer, the silicon wafer being boron doped and having a resistivity of less than 20 mohm-cm;
polishing the silicon wafer in a first polishing step after annealing the silicon wafer, the first polishing step being a double-side polish;
polishing the silicon wafer in a second polishing step after the first polishing step, the second polishing step being a finish polish;
inspecting the silicon wafer for defects in an inspection step, the inspection step being after the second polishing step, the inspection step comprising:
directing light to a front surface of the silicon wafer and detecting scattered reflected light; and
identifying light scattering events on the front surface of the silicon wafer based on the reflected light.

2. The method as set forth in claim 1 wherein the silicon wafer is annealed to at least 1000° C. for at least 1 hour.

3. The method as set forth in claim 1 wherein the silicon wafer is annealed to at least 1000° C. for at least 2 hours.

4. The method as set forth in claim 1 wherein the silicon wafer is annealed to at least 1000° C. for at least 4 hours.

5. The method as set forth in claim 1 wherein:
(1) directing light to a front surface of the silicon wafer and detecting scattered reflected light and (2) identifying light scattering events on the front surface of the silicon wafer based on the reflected light comprises:
placing the silicon wafer on a wafer inspection tool; and
operating the wafer inspection tool to inspect the silicon wafer for defects.

6. The method as set forth in claim 5 wherein the wafer inspection tool outputs a particle map of the silicon wafer.

7. The method as set forth in claim 1 wherein the silicon wafer has a resistivity of less than 15 mohm-cm.

8. The method as set forth in claim 1 wherein the silicon wafer has a resistivity of less than 10 mohm-cm.

9. The method as set forth in claim 1 wherein the silicon wafer has a resistivity of at least 5 mohm-cm.

10. The method as set forth in claim 1 wherein:
the first polishing step is proceeded by an initial wafer polishing sequence comprising:
polishing the silicon wafer in a double-side polish; and
polishing the silicon wafer in a finish polish after the double-side polish.

11. The method as set forth in claim 1 wherein the silicon wafer is a first silicon wafer, the method comprising:
polishing a second silicon wafer in the first polishing step, the second silicon wafer being boron doped and having a resistivity of less than 20 mohm-cm;
polishing the second silicon wafer in a second polishing step after the first polishing step, the second polishing step being a finish polish;
inspecting the second silicon wafer for defects in the wafer inspection step, the inspection step being after the second polishing step, the second silicon wafer not being annealed before the silicon wafer inspection step; and
comparing a density of light scattering events on the front surface of the first silicon wafer to a density of light scattering events on the front surface of the second silicon wafer.

12. A method for producing silicon wafers with reduced defects, the method comprising:
detecting oxygen precipitates according to the method of claim 11:
heating a charge of silicon disposed within a crucible to cause a silicon melt to form in the crucible;
contacting a silicon seed crystal with the silicon melt; and
withdrawing the silicon seed crystal to grow a single crystal silicon ingot, wherein one or more growth conditions of the single crystal silicon ingot are selected based on, at least in part, the comparison of the density of light scattering events on the front surface of the first silicon wafer to the density of light scattering events on the front surface of the second silicon wafer.
